(19) United States
(12) Patent Application Publication
(10) Pub. No.: US 2023/0418902 A1
(43) Pub. Date: Dec. 28, 2023

(54) METHODS AND SYSTEMS FOR CONSTRUCTING SENSING MATRICES

(71) Applicant: ALGORITHMIC BIOLOGICS PRIVATE LIMITED, Bangalore (IN)

(72) Inventor: Manoj Gopalkrishnan, Mumbai (IN)

(21) Appl. No.: 18/037,332

(22) PCT Filed: Nov. 16, 2021
(86) PCT No.: PCT/IN2021/051074

§ 371 Date: May 17, 2023

(51) Int. Cl. G06F 17/16

(52) U.S. Cl. CPC G06F 17/16

(57) ABSTRACT

Embodiments disclosed herein relate to sensing matrices and more particularly to easy-implementable sensing matrices with good recovery properties. Embodiments herein disclose methods and systems for constructing sensing matrices, wherein the sensing matrices are easy-to-implement and have good recovery properties.

### CROSS REFERENCE TO RELATED APPLICATION

This application is based on and derives the benefit of PCT Application PCT/IN2021/051074, the contents of which are incorporated herein by reference.

### TECHNICAL FIELD

Embodiments disclosed herein relate to sensing matrices, and more particularly to construct sensing matrices with good recovery properties.

### BACKGROUND

Sensing matrices (may also be referred as pooling matrices, or linear codes depending on the context) are used in compressed sensing and group testing applications, and in error correction. Examples include combinatorial pooling for biological assay testing, low-density parity-check (LDPC) codes in error correction, single-pixel cameras, Magnetic Resonance Imaging (MRI) image reconstruction, and so on. In an example, the sensing matrices may have ‘In’ number of rows and a large (n>>m) number of columns, wherein n>>m. The sensing matrices encode information from a high dimensional space of dimension equal to the number of columns into a low dimensional space of dimension equal to the number of rows. Such an encoding may be typically performed by matrix multiplication.

In conventional approaches, there may be two conflicting requirements on the sensing matrix: implementability and quality of recovery.

Implementability may be the ease of implementing the sensing matrix in the real world. In the conventional approaches, the implementation of the sensing matrix may involve drawbacks, if the sensing matrix has entries that have to be described to a very high level of precision. Ideally, the entries of the sensing matrix have to be restricted to a few well-spaced levels. In many applications, two levels (0 and 1) may be preferred. If the sensing matrix is dense (many non-zero entries), cost of implementing such a sensing matrix may be scaled as O(m*n), the number of non-zero entries. Any dependence on ‘n’ more than logarithmic enables the scheme to be impractical, since typically ‘n’ is much larger than ‘m’. If the sensing matrix is sparse and if the implementation has to proceed column by column, then the cost of implementing the sensing matrix still remains O(n). Therefore, such an implementation of the sensing matrix is still infeasible. Further, complexity of implementing the sensing matrix needs to be of the order O(m) of the number of rows ‘m’ and not of the order of the number of columns ‘n’. Such an implementation requires that the sensing matrix be sparse (few non-zero entries) and regular enough to permit the sensing matrix to be implemented in a parallel fashion row by row instead of entry by entry.

Quality of recovery is a measure of how well the sensing matrix is able to compress data that is being sensed by the sensing matrix, and how much of the data can be recovered. Prior to embodiments disclosed herein, all sensing matrices that are known to be optimal for the quality of recovery are dense (many non-zero entries, large variations in magnitude of entries). Many of the sensing matrices are constructed with random entries. A few deterministic constructions may exist, but they do not admit easy parallelization, making them hard (i.e., O(n) instead of O(m) effort) to implement.

### OBJECTS

The principal object of embodiments herein is to disclose methods and systems for constructing sensing matrices that are highly implementable while retaining high quality of recovery.

These and other aspects of the embodiments herein will be better appreciated and understood when considered in conjunction with the following description and the accompanying drawings. It should be understood, however, that the following descriptions, while indicating at least one embodiment and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF FIGURES

Embodiments herein are illustrated in the accompanying drawings, through out which like reference letters indicate corresponding parts in the various figures. The embodiments herein will be better understood from the following description with reference to the drawings, in which:

FIG. 1 depicts an electronic device configured to construct sensing matrices, according to embodiments as disclosed herein;

FIG. 2 depicts a sensing matrix constructor performable in the electronic device to construct the sensing matrix, according to embodiments as disclosed herein.

FIG. 3 depicts construction of the sensing matrix for an example rectangular grid, wherein the rectangular grid comprises of 96 objects arranged in an 8×12 grid, according to embodiments as disclosed herein;

FIG. 4 depicts construction of the sensing matrix for an example rectangular grid, wherein k grids of dimension h×b with h≤11, then a matrix is created with k×(h+2b) rows and k×h×b columns, according to embodiments as disclosed herein;

FIG. 5 is a flow diagram depicting a method for constructing the sensing matrix, according to embodiments as disclosed herein;

FIG. 6 is a flow diagram depicting a method for constructing the sensing matrix for the rectangular grid of dimension h×b with h≤b, according to embodiments as disclosed herein;

FIG. 7 is a flow diagram depicting a method for constructing the plurality of sensing matrices, according to embodiments as disclosed herein; and

FIG. 8 is a flow diagram depicting a method for constructing the sensing matrix by handling k number of rectangular grids, wherein each rectangular grid has the dimension of h×b, according to embodiments as disclosed herein.

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

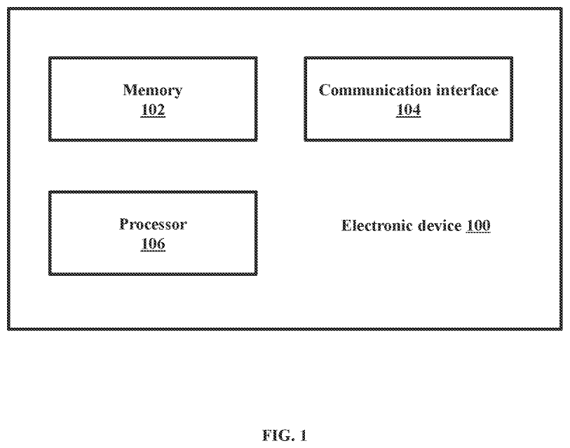

Embodiments herein disclose methods and systems for constructing easily implementable sensing matrices with good recovery properties. Referring now to the drawings, and more particularly to FIGS. 1 through 8, where similar reference characters denote corresponding features consistently throughout the figures, there are shown embodiments.

FIG. 1 depicts an electronic device 100 configured to construct sensing matrices, according to embodiments as disclosed herein.

The electronic device 100 referred herein may be configured to construct the sensing matrices. The electronic device 100 may be at least one of a cloud computing device, a server, a computing device, and so on. The cloud computing device may be a part of a public cloud or a private cloud. The server may be at least one of a standalone server, a server on a cloud, or the like. The computing device may be, but are not limited to, a personal computer, a notebook, a tablet, desktop computer, a laptop, a handheld device, a mobile device, and so on. Also, the electronic device 100 may be at least one of, a microcontroller, a processor, a System on Chip (SoC), an integrated chip (IC), a microprocessor based programmable consumer electronic device, and so on.

In an example, the sensing matrices may be widely employed in compressed sensing, group testing, and error correction. In another example, the sensing matrices may be employed in multiple fields such as, but are not limited to, single-pixel cameras, Magnetic resonance imaging (MRI) machines, communications technology, medical diagnostics, and so on. A sensing matrix has to be affected in real-world, which limits how complicated the sensing matrix has to be. For example, the sensing matrix with sparse entries (almost 0's) closet to optimum may be a major advance in the fields of the error correction, communications technology, or the like. The sensing matrix encodes information from a high dimensional space of dimension equal to a number of columns into a low dimensional space of dimension equal to a number of rows. Embodiments herein use the terms “sensing matrices”, “pooling matrices”, “linear codes”, and so on, interchangeably based on a context of implementing the matrix.

In an embodiment, the electronic device 100 may be configured to construct the sensing matrix(ces), that may be highly implementable while retaining high quality of recovery. Entries of the sensing matrix may be sparse based on 0-1 entries (though some variants allow multiple levels as well) and deterministic. The sensing matrix may allow parallelization in implementation and retain signal recovery properties.

The electronic device 100 includes a memory 102, a communication interface 104, and a processor 106.

The memory 102 includes at least one of, the sensing matrices, outputs processed by the processor 106, and so on. The memory 102 also includes a sensing matrix constructor 200, which may be executed by the processor 106 to construct the sensing matrices. The memory 102 may include at least one type of storage medium, from among a flash memory type storage medium, a hard disk type storage medium, a multi-media card micro type storage medium, a card type memory (for example, an SD or an XD memory), random-access memory (RAM), static RAM (SRAM), read-only memory (ROM), electrically erasable programmable ROM (EEPROM), programmable ROM (PROM), a magnetic memory, a magnetic disk, or an optical disk.

The communication interface 104 may be configured to enable the electronic device 100 to communicate with an external entity using a communication network. Examples of the external entity may be, but are not limited to, another electronic device, an external server, an external database, and so on. Examples of the communication network may be, but are not limited to, the Internet, a wired network, a wireless network (a Wi-Fi network, a cellular network, a Wi-Fi Hotspot, Bluetooth, Zigbee and so on) and so on.

The processor 106 may be configured to construct the sensing matrices with good signal recovery properties. For constructing the sensing matrix, the processor 106 receives information about a number of objects. The number of objects may be defined based on the context/field, in which the sensing matrix may be implemented. In an example, the number of objects may correspond to a number of biological samples, while using the sensing matrix in the field of pooled testing/biological assay testing, or the like. The processor 106 may receive the information about the number of objects from the external entity. On receiving the information about the number of objects, the processor 106 arranges the number of objects in a rectangular grid and constructs the sensing matrix for the rectangular grid. The constructed sensing matrix may include entries of 0-1, and each column has only 3 non-zero entries.

In an embodiment, consider herein that the rectangular grid has a dimension of h×b, wherein h and b depict rows and columns of the rectangular grid, wherein h≤b. In such a scenario, the processor 106 may construct the sensing matrix with the dimension of m=h+2b and n=h×b using three rectangular strips, wherein the m indicates a number of rows and the n indicates a number of columns. The first strip may be a vertical strip, which may be arranged vertically across the rectangular grid. The second strip may be a horizontal strip, which may be arranged horizontally across the rectangular grid. The third strip may be a slanted/diagonal strip, which may be arranged across the rectangular grid at the pre-defined angle. In an example, the slanted grip may present across the rectangular grid at 135 degrees.

For constructing the sensing matrix for the rectangular grid of dimension h×b, the processor 106 obtains a first b rows of the sensing matrix by sliding the vertical strip horizontally across columns of the rectangular grid. On obtaining the first b rows of the sensing matrix, the processor 106 obtains a next h rows of the sensing matrix by sliding the horizontal strip vertically across the rows of the rectangular grid. On obtaining the next h rows of the sensing matrix, the processor 106 folds the rectangular grid into a cylinder by bringing a first column of the rectangular gird adjacent to a last column of the rectangular grid. On folding the rectangular grid into the cylinder, the processor 106 obtains a last b rows of the sensing matrix by sliding the slanted strip across the folded rectangular grid at the pre-defined angle. The constructed sensing matrix has three 1s in each column since each object participates is picked up one time by each of the three strips.

Embodiments herein enable the processor 106 to increase flexibility in terms of allowing the construction of the sensing matrices with various values of m (both smaller and larger) for a given n number of columns. The processor 106 may construct the sensing matrices for the various values of m separately or combined together.

In an embodiment, the processor 106 may be configured to construct the plurality of sensing matrices. In an example herein, consider that h1 and b1 are the rectangular grid in a stage 1. For such a rectangular grid, the processor 106 may obtain a first stage sensing matrix with dimensions m₁=h₁+2b₁ and n₁=h₁b₁. The processor 106 may choose h₂ and b₂, such that h₂b₂=m₁. The processor 106 then obtains the second stage sensing matrix corresponding to the first stage sensing matrix with small grid. The second stage sensing matrix may have dimensions of m₂=h₂+2b₂ and n₂=h₂b₂. The processor 106 multiplies the first stage sensing matrix with the second stage sensing matrix to generate a single third stage sensing matrix with dimensions of (h₂+2b₂)×h₁b₁. The processor 106 may continue above described multiplication in iteration beyond two times to create a sequence of sensing matrices that have number of rows as small as desired for the given number of columns.

In an embodiment, the processor 106 may be configured to construct the sensing matrix, wherein each column of the sensing matrix has four 1s. The processor 106 may add a fourth strip across the folded rectangular grid at a suitable angle. In an example, the processor 106 may add the fourth strip across the folded rectangular strip at an angle of 45 degrees. In such a scenario, each column of the sensing matrix has four 1s instead of three 1 s, which preserves a property that a dot product of two columns of the sensing matrix is at most 1.

In an embodiment, the processor 106 may be configured to construct the sensing matrix while handling multiple grids of same size. In an example, consider that there are k rectangular grids of dimension h×b with h≤b. In such a scenario, the processor 106 constructs the sensing matrix having the dimension of k×(h+2b) rows and k×h×b columns. For constructing the sensing matrix, the processor 106 numbers the k rectangular grids as Grid 1, Grid 2, . . . , Grid k and arranges the k rectangular grids side-to-side with the 12th column of the rectangular grid i abutting a 1st column of the rectangular grid (i+1). On numbering the k rectangular grids, the processor 106 slides the vertical strip across each of the rectangular grids in turn to obtain a first k×b rows of the sensing matrix. The processor 106 slides the horizontal strip across each of the rectangular grids in turn to obtain a next k×h rows of the sensing matrix. The processor 106 folds the arranged k rectangular grids into the cylinder, by bringing the 12^{th} column of the rectangular grid k (Grid k) adjacent to the 1^{st} column of the rectangular grid 1 (Grid 1). The processor 106 slides the slanted/diagonal strip around the cylinder to obtain a last k×b rows of the sensing matrix.

Embodiments herein explain implementation of the sensing matrix in the field of pooled testing, as an example, but it may be obvious to a person skilled in the art that the sensing matrix may be constructed and implemented in any other applications/fields. In an example herein, the pooled testing may be performed to determine the viruses present in biological samples of individuals/humans. In an embodiment, the viruses may be single-stranded Ribonucleic acid (RNA) viruses. Examples of the viruses may be, but are not limited to, Coronavirus disease of 2019 (COVID-19), Severe Acute Respiratory Syndrome (SARS), Poliovirus, Rhinovirus, Hepatitis A virus or any other virus that may be tested based on extraction of RNA from the biological samples.

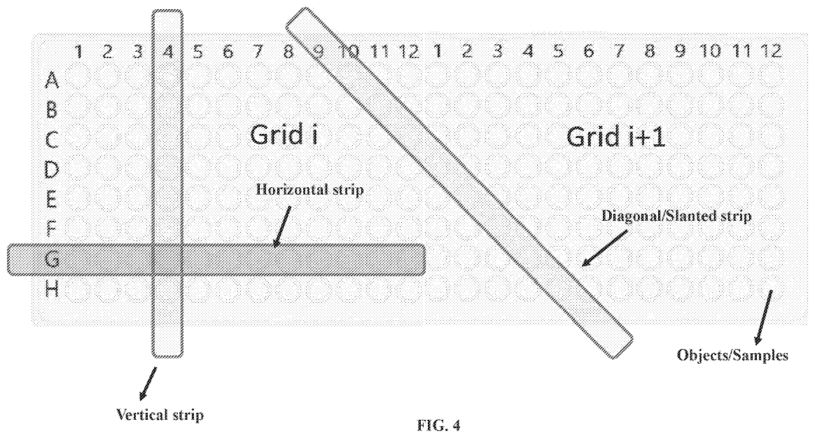

The processor 106 receives a request for instructions related to pooling and testing of the biological samples from a user through the external entity. The request includes a size of the test indicating a number of biological samples/objects to be tested and a number of positives estimated. The processor 106 arranges the objects in the rectangular grid. The processor 106 constructs the sensing matrix/pooling matrix for the rectangular grid using the three strips arranged across the rectangular grid. The constructed sensing matrix may be the sparse matrix including the plurality of rows and the plurality of columns with entries of 0-1, wherein each column has three non-zero entries. The number of rows of the sensing matrix indicate a number of pools to be created for testing the plurality of biological samples. The number of columns of the sensing matrix indicate the number of biological samples to be tested. The non-zero entries present in each column indicate the pools for including each biological sample. Construction of the sensing matrix for an example rectangular grid of biological samples is described in detail in conjunction with FIG. 4.

On constructing the sensing matrix, the processor 106 provides instructions to the user indicating the number of pools required for the requested size of the test and the three different pools (corresponding to the three non-zero entries of each column) for each biological sample. On receiving the instructions, the user performs the pooling of the biological samples by pipetting each biological sample into the indicated three different pools/wells of a PCR reaction plate. The user performs the RT-qPCR test on each pool and determines input cycle threshold (Ct) values of each pool. The user may communicate the Ct values to the electronic device 100 or the external entity. The processor 106 of the electronic device 100 or the external entity may use the Ct values of each pool to determine/recover a status of each biological sample. The status of the biological sample indicates whether the virus is present or not in the corresponding biological sample.

Sensing matrices, as disclosed herein, can be used for performing pooling and testing of biological samples and recovering the status of the biological samples using the Ct values, as further disclosed in Indian Patent Application 202021051801.

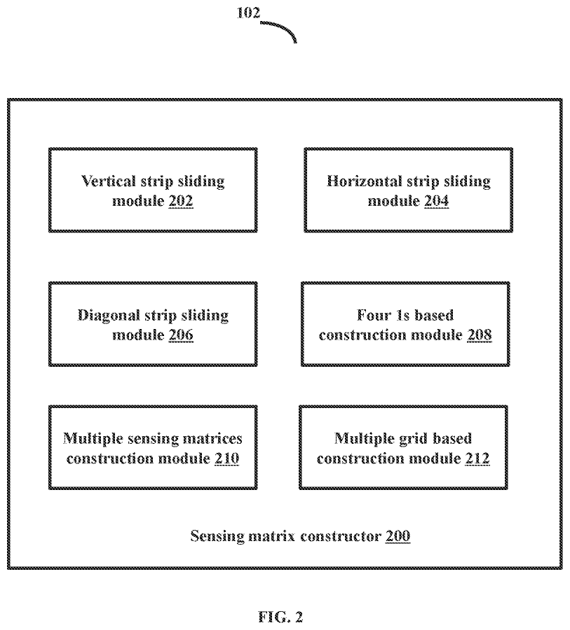

FIG. 2 depicts the sensing matrix constructor 200 performable in the electronic device 100 to construct the sensing matrix, according to embodiments as disclosed herein.

The sensing matrix constructor 200 may be executed by the processor 106 to construct the sensing matrix. The sensing matrix constructor 200 includes a vertical strip sliding module 202, a horizontal strip sliding module 204, a diagonal strip sliding module 206, a four 1s based construction module 208, a multiple sensing matrices construction module 210, and a multiple grid based construction module 212.

In an embodiment, the sensing matrix may be constructed for the rectangular grid of dimension h×b, where h≤b. The sensing matrix may have m number of rows and n number of columns, wherein m=h+2b and n=h×b.

The vertical strip sliding module 202 may be configured to obtain the first b rows of the sensing matrix. The vertical strip sliding module 202 slides the vertical strip/first strip horizontally across the columns of the rectangular grid to obtain the first b rows of the sensing matrix.

The horizontal strip sliding module 204 may be configured to obtain the next h rows of the sensing matrix. The horizontal strip sliding module 204 slides the horizontal strip/second strip vertically across the rows of the rectangular grid to obtain the next h rows of the sensing matrix.

The diagonal strip sliding module 206 may be configured to obtain the last b rows of the sensing matrix. The diagonal strip sliding module 206 folds the rectangular grid into the cylinder by bringing the first column of the rectangular grid adjacent to the last column of the rectangular grid. The diagonal strip sliding module 206 slides the slanted strip across the folded rectangular grid/cylinder at the pre-defined angle to obtain the last b rows of the sensing matrix.

The four is based construction module 208 may be configured to construct the sensing matrix, wherein each column of the sensing matrix has entries of four 1s. The four 1s based construction module 208 uses the fourth strip arranged across the rectangular grid to construct the sensing matrix with four is in each column.

The multiple sensing matrices construction module 210 may be configured to construct the plurality of sensing matrices. The multiple sensing matrices construction module 210 constructs the first stage sensing matrix for the given rectangular grid. The multiple sensing matrices construction module 210 constructs the second stage sensing matrix by considering the first stage of sensing matrix as the small rectangular grid. The multiple sensing matrices construction module 210 multiplies the first stage sensing matrix with the second stage sensing matrix to obtain the third stage sensing matrix. The multiple sensing matrices construction module 210 performs the multiplication of a constructed stage sensing matrix with a previous stage sensing matrix in iterations to obtain successive stage sensing matrices in sequence. The constructed stage sensing matrix corresponds to the third stage sensing matrix or the corresponding successive stage sensing matrices (for example, fourth stage sensing matrix, fifth stage sensing matrix, or the like). The previous stage sensing matrix corresponds to the third stage sensing matrix or the corresponding successive stage sensing matrices (for example, third stage sensing matrix, fourth stage sensing matrix, or the like).

The multiple grid based construction module 212 may be configured to construct the sensing matrix by handling k rectangular grids, wherein each rectangular grid has dimension of h×b. The multiple grid based construction module 212 numbers the k rectangular grids and arranges the k rectangular grids side-to-side with the 12^{th} column of the rectangular grid i abutting the 1^{st} column of the rectangular grid (i+1). The multiple grid based construction module 212 slides the first strip across each of the k rectangular grids to obtain the first k×b rows of the sensing matrix. The multiple grid based construction module 212 slides the second strip across each of the rectangular grids to obtain the next k×h rows of the sensing matrix. The multiple grid based construction module 212 folds the arranged k rectangular grids into the cylinder, by bringing the 12^{th} column of the k^{th} rectangular grid adjacent to the 1^{st} column of the 1^{st} rectangular grid. The multiple grid based construction module 212 slides the diagonal strip around the cylinder to obtain the last k×b rows of the sensing matrix.

FIGS. 1 and 2 show exemplary blocks of the electronic device 100, but it is to be understood that other embodiments are not limited thereon. In other embodiments, the electronic device 100 may include less or a greater number of blocks. Further, the labels or names of the blocks are used only for illustrative purpose and do not limit the scope of the embodiments herein. One or more blocks can be combined together to perform the same or substantially similar function in the electronic device 100.

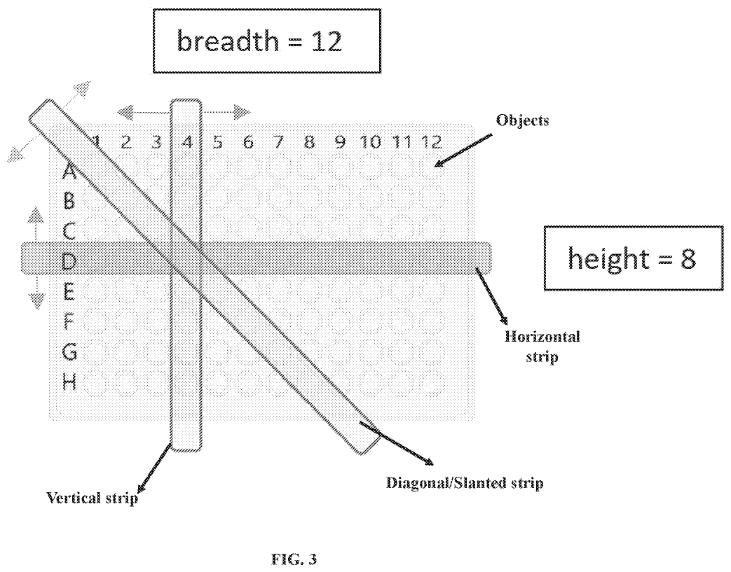

FIG. 3 depicts construction of the sensing matrix for an example rectangular grid, wherein the rectangular grid comprises of 96 objects arranged in an 8×12 grid, according to embodiments as disclosed herein.

Consider an example scenario, wherein the electronic device 100 receives an example rectangular grid for creating the sensing matrix. The example rectangular grid comprises of 96 objects arranged in an 8×12 grid. In the example rectangular grid, the objects are denoted by circles. For such a rectangular grid, the electronic device 100 constructs the sensing matrix with 32 rows and 96 columns and with entries of 0-1. The electronic device 100 obtains the 32 rows of the sensing matrix using the three strips arranged vertically, horizontally, and diagonally on a top of the rectangular grid. The electronic device 100 obtains the first 12 rows of the matrix by sliding the vertical strip from left to right. The electronic device 100 obtains the next 8 rows by sliding the horizontal strip from top to bottom. The electronic device 100 obtains the last 12 rows by folding the rectangular grid into the cylinder by bringing the first column adjacent to the 12th column and sliding the slanted/diagonal strip across the cylinder at the pre-defined angle (for example: at an angle of 135°).

The electronic device 100 slides the vertical strip from left to right while keeping the vertical strip vertical across the rectangular grid. The vertical strip has 12 positions available to it. In a first position, the vertical strip overlaps with the objects in a column 1 in positions A1, B1, C1, . . . , H1. In a second position, the vertical strip overlaps with a column 2. Finally, in a 12th position, the vertical strip overlaps with column 12. These twelve positions encode the first twelve rows of the sensing matrix. The columns of the sensing matrix may be numbered from A1 to H12, corresponding to the positions of objects in the rectangular grid. A 1st row of the sensing matrix includes the entry “1” in the columns A1, B1, . . . , H1, and the entry “0” in all other columns. Similarly, a 3rd row of the sensing matrix includes the entry “1” in the columns A3, B3, . . . , H3, and the entry “0” in all other columns, and so on.

The electronic device 100 slides the horizontal strip from top to bottom while keeping the horizontal strip horizontal across the rectangular grid. The horizontal strip has 8 positions available to it. In a first position, the horizontal strip overlaps with the objects in positions A1, A2, A3, . . . , A12. In a second position, the horizontal strip overlaps with row B. Finally, in an 8th position, the horizontal strip overlaps with row H. These 8 positions encode the rows 13 to 20 of the sensing matrix. A 13th row of the sensing matrix includes the entry “1” in the columns A1, A2, . . . , A12, and the entry “0” in all other columns. Similarly, a 15th row of the matrix includes the entry “1” in the columns C1, C2, . . . , C12, and the entry “0” in all other columns, and so on.

The electronic device 100 rolls/folds the rectangular grid into the cylinder of height 8 and circumference 12. The electronic device 100 folds the rectangular grid into the cylinder by making A12 adjacent to A1, B12 adjacent to B1, . . . , and H12 adjacent to H1, which means that a diagonal starting at position A11 continues as B12, C1, D2, E3, F4, G5, H6. To obtain all the height=8, breadth=12 diagonals, the electronic device 100 slides the diagonal/slanted strip around the cylinder while keeping its angle unchanged. The diagonal/slanted strip has 12 positions available to it, corresponding to A1 to A12. In a first position, the diagonal/slanted strip overlaps with the objects in positions A1, B2, C3, D4, E5, F6, G7, H8 as indicated. In a second position, the diagonal/slanted strip overlaps with A2, B3, C4, D5, E6, F7, G8, and H9. Finally, in a 12th position, the diagonal/slanted strip overlaps with the diagonal starting at position A11 described above. These 12 positions encode the rows 21 to 32 of the sensing matrix. A 21st row of the matrix includes the entry “1” in the columns A1, B2, . . . , H8, and the entry “0” in all other columns. Similarly, a 23rd row of the matrix includes the entry “1” in the columns A3, B4, . . . , H10, and the entry “0” in all other columns, and so on. A 31st row includes the entry “1” in the diagonal starting at position A11.

FIG. 4 depicts construction of the sensing matrix for an example rectangular grid, wherein k rectangular grids of dimension h×b with h≤b, then the sensing matrix is created with k×(h+2b) rows and k×h×b columns, according to embodiments as disclosed herein.

Embodiments herein explain the construction of sensing matrix for pooled testing, as an example, but it may be obvious to a person skilled in the art that the sensing matrix may be constructed and deployed in any other applications/fields. The pooled testing is a method of group testing used on biological assays, especially Quantitative reverse transcription PCR (RT-qPCR). In the pooled testing, if a pool tests negative, all biological samples in that pool are negative. The pools have to be prepared by pipetting exactly those biological samples participating in the pool into a tube for that pool. The cost for this implementation may be expressed as a number of pipetting steps.

The electronic device 100 may receive the information about the objects arranged in the rectangular grid from the external entity to construct the sensing matrix for an exemplary scenario of pooled testing. In such a scenario, each object in the rectangular grid represents a biological sample to be analyzed. In such a scenario, the sensing matrix may be referred as a pooling matrix. Each row of the sensing/pooling matrix represents a pool, and each column represents a sample. The 1s in the row represent the samples participating in that pool. An example rectangular grid may be depicted in FIG. 4. As depicted in FIG. 4, all the pipetting may be performed with 8-channel and 12-channel multi-pipettes in a many-to-many manner. The number of pipetting steps may be only 8+12+23=43. In general, for a h×b grid, the number of pipetting steps using a b-channel multi-pipette and an h-channel multi-pipette may be only h+b+2b−1=O (h+b).

The rectangular grid includes 8 rows/pools (hereinafter referred as row pools) A to H. Each row pool contains 12 samples. To prepare the row pools, an 8-channel multi-pipette is used. The pipette tips are arranged over a first column from A1 to H1, and a liquid is delivered into the corresponding pools A to H. Then, the pipette is moved over to a second column and repeat, and so on. At the end of 12 pipettings, all the columns are covered, and 8 pools have been prepared. A pool A contains samples A1, A2, . . . , A12. Similarly, a pool B contains samples B1, B2, . . . , B12, and so on.

The rectangular grid includes 1 to 12 columns (hereinafter referred as column pools). Each column pool contains 8 samples. To prepare the column pools, a 12-channel multi-pipette is used. The pipette tips are arranged over a first row from A1 to A12, and the liquid is delivered into the corresponding pools 1 to 12. Then, the pipette is moved over a second row and repeat, and so on. At the end of 8 pipettings, all the rows are covered, and 12 pools have been prepared. A pool 1 contains samples A1, B1, C1, . . . , H1. A pool 2 contains samples A2, B2, C2, . . . , H2, and so on.

The rectangular grid includes 12 diagonal pools which are labelled by the sample in a row A that uniquely belongs to that pool. Each diagonal pool contains 8 samples. So, the diagonal pool D-A1 contains the samples A1, B2, C3, D4, E5, F6, G7, H8. To prepare the diagonal pools, the 12-channel multi-pipette is used. The pipette tips are arranged over the first row from A1 to A12, and the liquid is delivered into the corresponding pools D-A1 to D-A12. Then, the pipette is shifted down by one and right by one, till the tips are over the wells B2 to B12. This gets pipetted into D-A1 to D-A11. The well B1 is separately pipetted into D-A12. Next, the pipette is shifted down and to the right by one. The tips are over C3 to C12, which go into D-A1 to DA10. C1 and C2 then go into D-A11 and D-A12. Proceeding in this manner, each row requires 2 pipettings, except the first row, for a total of 8+7=15 pipetting steps. At the end of these 15 pipettings, all the diagonals are covered, and 12 pools have been prepared.

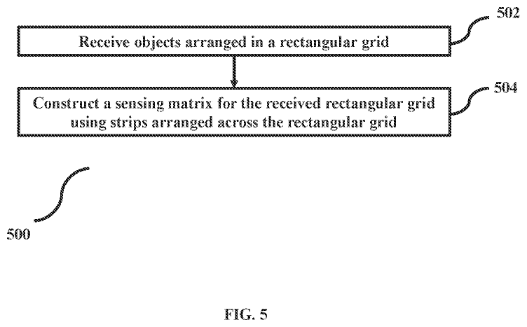

FIG. 5 is a flow diagram 500 depicting a method for constructing the sensing matrix, according to embodiments as disclosed herein.

At step 502, the method includes receiving, by the electronic device 100, the objects arranged in the rectangular grid.

At step 504, the method includes constructing, by the electronic device 100, the sensing matrix for the received rectangular grid using strips arranged across the rectangular grid. The sensing matrix includes the plurality of rows and the plurality of columns with three non-zero entries in each column. The various actions, acts, blocks, steps, or the like in the method and the flow diagram 500 may be performed in the order presented, in a different order or simultaneously. Further, in some embodiments, some of the actions, acts, blocks, steps, or the like may be omitted, added, modified, skipped, or the like without departing from the scope of the invention.

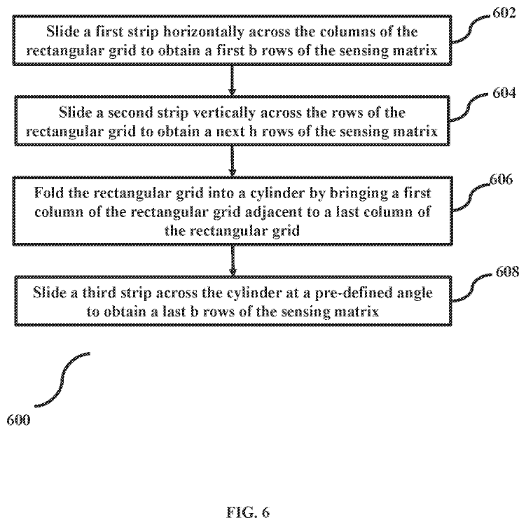

FIG. 6 is a flow diagram 600 depicting a method for constructing the sensing matrix for the rectangular grid of dimension h×b with h≤b, according to embodiments as disclosed herein.

At step 602, the method includes sliding, by the electronic device 100, the first/vertical strip horizontally across the columns of the rectangular grid to obtain the first b rows of the sensing matrix.

At step 604, the method includes sliding, by the electronic device 100, the second/horizontal strip vertically across the rows of the rectangular grid to obtain the next h rows of the sensing matrix.

At step 606, the method includes folding, by the electronic device 100, the rectangular grid into the cylinder by bringing the first column of the rectangular grid adjacent to the last column of the rectangular grid. At step 608, the method includes sliding, by the electronic device 100, the third/diagonal strip across the cylinder at the pre-defined angle to obtain the last b rows of the sensing matrix. The sensing matrix constructed for the rectangular grid of h×b may have the dimension of m=h+2b and n=h×b, wherein m and n indicate the number of rows and the number of columns of the sensing matrix, respectively. The various actions, acts, blocks, steps, or the like in the method and the flow diagram 600 may be performed in the order presented, in a different order or simultaneously. Further, in some embodiments, some of the actions, acts, blocks, steps, or the like may be omitted, added, modified, skipped, or the like without departing from the scope of the invention.

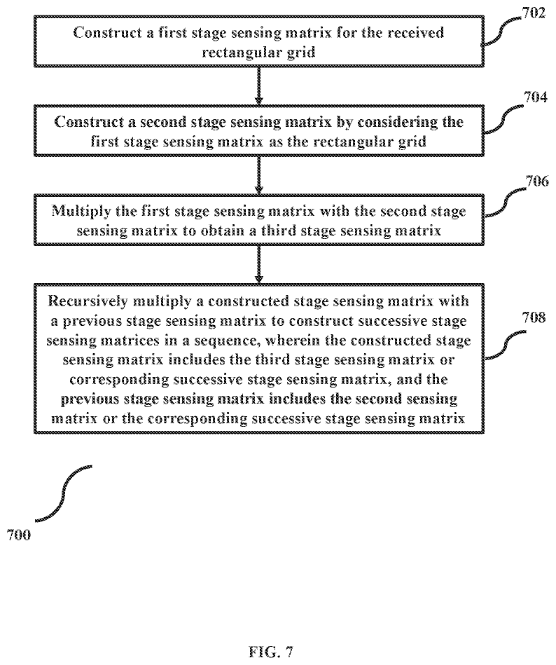

FIG. 7 is a flow diagram 700 depicting a method for constructing the plurality of sensing matrices, according to embodiments as disclosed herein.

At step 702, the method includes constructing, by the electronic device 100, the first stage sensing matrix for the received rectangular grid. At step 704, the method includes constructing, by the electronic device 100, the second stage sensing matrix by considering the first stage sensing matrix as the rectangular grid. At step 706, the method includes multiplying, by the electronic device 100, the first stage sensing matrix with the second stage sensing matrix to obtain the third stage sensing matrix.

At step 708, the method includes multiplying, by the electronic device 100, the constructed stage sensing matrix with the previous stage sensing matrix in iterations to construct the successive stage sensing matrices in a sequence, wherein the constructed stage sensing matrix includes the third stage sensing matrix or the corresponding successive stage sensing matrix, and the previous stage sensing matrix includes the second sensing matrix or the corresponding successive stage sensing matrix. The various actions, acts, blocks, steps, or the like in the method and the flow diagram 700 may be performed in the order presented, in a different order or simultaneously. Further, in some embodiments, some of the actions, acts, blocks, steps, or the like may be omitted, added, modified, skipped, or the like without departing from the scope of the invention.

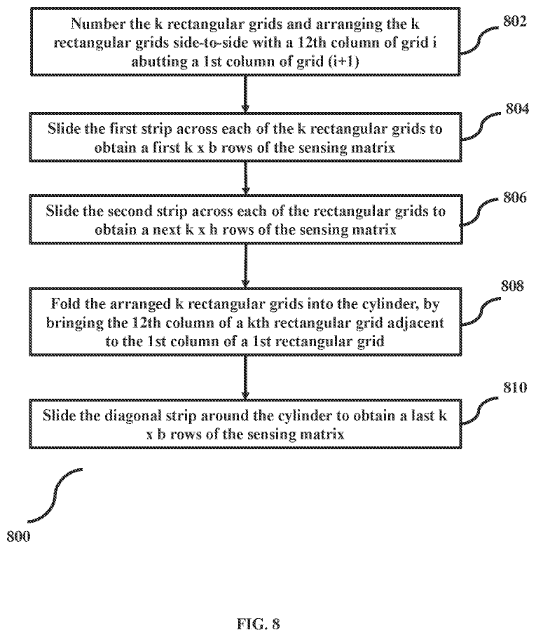

FIG. 8 is a flow diagram depicting a method for constructing the sensing matrix by handling the k number of rectangular grids, wherein each rectangular grid has the dimension of h×b, according to embodiments as disclosed herein.

At step 802, the method includes numbering, by the electronic device 100, the k rectangular grids and arranging, by the electronic device 100, the k rectangular grids side-to-side with a 12^{th} column of grid i abutting a 1^{st} column of grid (i+1).

At step 804, the method includes sliding, by the electronic device 100, the first strip across each of the k rectangular grids to obtain the first k×b rows of the sensing matrix.

At step 806, the method includes sliding, by the electronic device 100, the second strip across each of the rectangular grids to obtain the next k×h rows of the sensing matrix.

At step 808, the method includes folding, by the electronic device 100, the arranged k rectangular grids into the cylinder, by bringing the 12^{th} column of the k^{th} rectangular grid adjacent to the 1^{st} column of the 1^{st} rectangular grid. At step 810, the method includes sliding the diagonal strip around the cylinder to obtain the last k×b rows of the sensing matrix. The various actions, acts, blocks, steps, or the like in the method and the flow diagram 800 may be performed in the order presented, in a different order or simultaneously. Further, in some embodiments, some of the actions, acts, blocks, steps, or the like may be omitted, added, modified, skipped, or the like without departing from the scope of the invention.

Embodiments herein construct sensing matrices by having the following advantages, wherein the sensing matrices are easy-to-implement and have good recovery properties:
Sparse matrix: The sensing matrix is a sparse matrix that include entries of 0-1, and each column has only 3 non-zero entries, which reduces the implementation complexity from O(m×n) to O(n). The iterated construction of depth d may have up to 3d non-zero entries and multiple levels, but it explicitly describes how to construct the iterated matrix in an efficient manner
Steiner systems: A dot product of any two columns of the sensing matrix is at most 1, which ensures very good recovery properties.
Ease of implementation: The sensing matrix may be described in terms of moves of the strips; each strip is of size O(m). In many practical situations, these moves allow translation into parallel steps of creating rows of the matrix. Hence the implementation complexity may be brought down to O(m) instead of O(n) in many practical situations.

The embodiments disclosed herein may be implemented through at least one software program running on at least one hardware device and performing network management functions to control the elements. The elements shown in FIGS. 1 and 2, may be at least one of a hardware device, or a combination of hardware device and software module.

The embodiments disclosed herein describe methods and systems for constructing sensing matrices. Therefore, it is understood that the scope of the protection is extended to such a program and in addition to a computer readable means having a message therein, such computer readable storage means contain program code means for implementation of one or more steps of the method, when the program runs on a server or mobile device or any suitable programmable device. The method is implemented in a preferred embodiment through or together with a software program written in e.g., Very high speed integrated circuit Hardware Description Language (VHDL) another programming language, or implemented by one or more VHDL or several software modules being executed on at least one hardware device. The hardware device may be any kind of portable device that may be programmed. The device may also include means which could be e.g., hardware means like e.g., an ASIC, or a combination of hardware and software means, e.g., an ASIC and an FPGA, or at least one microprocessor and at least one memory with software modules located therein. The method embodiments described herein could be implemented partly in hardware and partly in software. Alternatively, the invention may be implemented on different hardware devices, e.g., using a plurality of CPUs.

The foregoing description of the specific embodiments will so fully reveal the general nature of the embodiments herein that others may, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of embodiments, those skilled in the art will recognize that the embodiments herein may be practiced with modification within the spirit and scope of the embodiments as described herein.

I/We claim:

1. A method for constructing sensing matrices, the method comprising:
receiving, by an electronic device (100), objects arranged in a rectangular grid; and
constructing, by the electronic device (100), a sensing matrix for the received rectangular grid using strips arranged across the rectangular grid, wherein the sensing matrix is a sparse matrix including entries of 0-1.

2. The method of claim 1, wherein
the sensing matrix includes a plurality of rows and a plurality of columns with three non-zero entries in each column;
the rectangular grid has a dimension of h×b, wherein h and b indicate rows and columns of the rectangular grid, wherein h is lesser than or equal to b; and
the constructed sensing matrix for the rectangular grid of h×b has a dimension of m=h+2b and n=h×b, wherein m and n indicate a number of rows and a number of columns of the sensing matrix, respectively.

3. The method of claim 2, wherein constructing the sensing matrix includes:
sliding a first strip horizontally across the columns of the rectangular grid to obtain a first b rows of the sensing matrix;
sliding a second strip vertically across the rows of the rectangular grid to obtain a next h rows of the sensing matrix;
folding the rectangular grid into a cylinder by bringing a first column of the rectangular grid adjacent to a last column of the rectangular grid; and
sliding a third strip across the cylinder at a pre-defined angle to obtain a last b rows of the sensing matrix.

4. The method of claim 3, wherein
the first strip is a vertical strip arranged vertically across the rectangular grid;
the second strip is a horizontal strip arranged horizontally across the rectangular grid; and
the third strip is a diagonal strip arranged across the rectangular grid at the pre-defined angle.

5. The method of claim 3, further comprising: constructing the sensing matrix with four non-zero entries in each column by sliding a fourth strip arranged across the folded rectangular grid at a pre-defined foldable angle.

6. The method of claim 1, further comprising: constructing, by the electronic device (100), a plurality of sensing matrices, wherein constructing the plurality of sensing matrices includes:
constructing, by the electronic device (100), a first stage sensing matrix for the received rectangular grid;
constructing, by the electronic device (100), a second stage sensing matrix by considering the first stage sensing matrix as the rectangular grid;
multiplying, by the electronic device (100), the first stage sensing matrix with the second stage sensing matrix to obtain a third stage sensing matrix; and
multiplying, by the electronic device (100), a constructed stage sensing matrix with a previous stage sensing matrix in iterations to construct successive stage sensing matrices in a sequence, wherein the constructed stage sensing matrix includes the third stage sensing matrix or corresponding successive stage sensing matrix, and the previous stage sensing matrix includes the second stage sensing matrix or the corresponding successive stage sensing matrix.

7. The method of claim 1, further comprising: constructing, by the electronic device (100), the sensing matrix for k number of rectangular grids, each rectangular grid has the dimension of h×b, wherein constructing the sensing matrix includes:
numbering the k rectangular grids and arranging the k rectangular grids side-to-side with a 12^{th} column of a rectangular grid i abutting a 1^{st} column of a rectangular grid (i+1);
sliding the first strip across each of the k rectangular grids to obtain a first k×b rows of the sensing matrix;
sliding the second strip across each of the rectangular grids to obtain a next k×h rows of the sensing matrix;
folding the arranged k rectangular grids into the cylinder, by bringing the 12^{th} column of a k^{th} rectangular grid adjacent to the 1^{st} column of a 1^{st} rectangular grid; and
sliding the diagonal strip around the cylinder to obtain a last k×b rows of the sensing matrix.

8. An electronic device (100) comprising:
a memory (102); and
a processor (106) coupled to the memory (102) configured to:
receive objects arranged in a rectangular grid; and
construct a sensing matrix for the received rectangular grid, using strips arranged across the rectangular grid, wherein the sensing matrix is a sparse matrix includes entries of 0 or 1.

9. The electronic device (100) of claim 8, wherein
the sensing matrix includes a plurality of rows and a plurality of columns with three non-zero entries in each column;
the rectangular grid has a dimension of h×b, wherein h and b indicate rows and columns of the rectangular grid, wherein h is lesser than or equal to b; and
the constructed sensing matrix for the rectangular grid of h×b has a dimension of m=h+2b and n=h×b, wherein m and n indicate a number of rows and a number of columns of the sensing matrix, respectively.

10. The electronic device (100) of claim 9, wherein the processor (106) is configured to construct the sensing matrix by:
sliding a first strip horizontally across the columns of the rectangular grid to obtain a first b rows of the sensing matrix;
sliding a second strip vertically across the rows of the rectangular grid to obtain a next h rows of the sensing matrix;
folding the rectangular grid into a cylinder by bringing a first column of the rectangular grid adjacent to a last column of the rectangular grid; and
sliding a third strip across the cylinder at a pre-defined angle to obtain a last b rows of the sensing matrix.

11. The electronic device (100) of claim 10, wherein
the first strip is a vertical strip arranged vertically across the rectangular grid;
the second strip is a horizontal strip arranged horizontally across the rectangular grid; and
the third strip is a diagonal strip arranged across the rectangular grid at the pre-defined angle.

12. The electronic device (100) of claim 10, wherein the processor (106) is further configured to construct the sensing matrix with four non-zero entries in each column by sliding a fourth strip arranged across the folded rectangular grid at a pre-defined foldable angle.

13. The electronic device (100) of claim 8, wherein the processor (106) is further configured to construct a plurality of sensing matrices by:
constructing, by the electronic device (100), a first stage sensing matrix for the received rectangular grid;
constructing, by the electronic device (100), a second stage sensing matrix by considering the first stage sensing matrix as the rectangular grid;
multiplying, by the electronic device (100), the first stage sensing matrix with the second stage sensing matrix to obtain a third stage sensing matrix; and
multiplying, by the electronic device (100), a constructed stage sensing matrix with a previous stage sensing matrix in iterations to construct successive stage sensing matrices in a sequence, wherein the constructed stage sensing matrix includes the third stage sensing matrix or corresponding successive stage sensing matrix, and the previous stage sensing matrix includes the second stage sensing matrix or the corresponding successive stage sensing matrix.

14. The electronic device (100) of claim 8, wherein the processor (106) is further configured to construct the sensing matrix for k number of rectangular grids, each rectangular grid has the dimension of h×b by:
numbering the k rectangular grids and arranging the k rectangular grids side-to-side with a 12^{th} column of a rectangular grid i abutting a 1^{st} column of a rectangular grid (i+1);
sliding the first strip across each of the k rectangular grids to obtain a first k×b rows of the sensing matrix;
sliding the second strip across each of the rectangular grids to obtain a next k×h rows of the sensing matrix;
folding the arranged k rectangular grids into the cylinder, by bringing the 12^{th} column of a k^{th} rectangular grid adjacent to the 1^{st} column of a 1^{st} rectangular grid; and
sliding the diagonal strip around the cylinder to obtain a last k×b rows of the sensing matrix.
